(19) United States
(12) Patent Application Publication
(10) Pub. No.: US 2025/0089192 A1
(43) Pub. Date: Mar. 13, 2025

(54) COMPOSITE BACKPLATE ARCHITECTURES FOR BACKSIDE POWER DELIVERY AND ASSOCIATED METHODS

(71) Applicant: Intel Corporation, Santa Clara, CA (US)

(72) Inventors: Phil Geng, Washougal, WA (US); Dongwang Chen, Shanghai (CN); Fernando Gonzalez Lenero, Zapopan (MX); Chuansheng Liu, Shanghai (CN); Lejie Liu, Portland, OR (US); Ralph V. Miele, Hillsboro, OR (US); Mohanraj Prabhugoud, Hillsboro, OR (US); Sanjoy Saha, Portland, OR (US); David Shia, Portland, OR (US); Jeffory L. Smalley, East Olympia, WA (US); Ke Song, Shanghai (CN); Meng Wang, Shanghai (CN); Xiaoning Ye, Portland, OR (US); Juan Zermeno Carriedo, Guadalajara (MX); Yipeng Zhong, Shanghai (CN)

(73) Assignee: Intel Corporation, Santa Clara, CA (US)

(21) Appl. No.: 18/961,017

(22) Filed: Nov. 26, 2024

Related U.S. Application Data
(63) Continuation of application No. PCT/CN2024/126034, filed on Oct. 21, 2024.

(30) Foreign Application Priority Data
Oct. 21, 2024 (WO) PCT/CN2024/126034

(51) Int. Cl. H05K 5/02; H05K 5/04

(52) U.S. Cl. CPC H05K 5/0247; H05K 5/04

(57) ABSTRACT

Composite backplate architectures for backside power delivery and associated methods are disclosed. An example backplate includes a first layer including a first material, and a second layer attached to the first layer. The second layer includes a second material different from the first material. The example backplate further includes a bus bar attached to the first layer.

### RELATED APPLICATIONS

This patent arises from International Application No. PCT/CN2024/126034, which was filed on Oct. 21, 2024. International Application No. PCT/CN2024/126034 is hereby incorporated herein by reference in its entirety. Priority to International Application No. PCT/CN2024/126034 is hereby claimed.

### BACKGROUND

The demand for greater computing power and faster computing times continues to grow. This has led to higher-density connectors on computer hardware components to transfer signals more quickly. Some processor chips are communicatively coupled to printed circuit boards (PCBs) via sockets constructed to receive and electrically couple to contacts on the processor chips. Often a heatsink is mechanically and thermally coupled to the processor chip to facilitate the dissipation of heat generated by the processor chip. In some instances, the heatsink also provides a compressive load on the processor chip to ensure electrical connection between the chip and the associated socket. Further, in some instances, a backplate is attached to a backside of a printed circuit board carrying the socket to provide structural support to the assembly and reduce warpage that can result from the compressive loads produced by the heatsink.

### BRIEF DESCRIPTION OF THE DRAWINGS

FIG. 1 is an exploded view of a known IC package heat dissipating component stack.

FIG. 2 is an enlarged view of the known backplate of FIG. 1.

FIG. 3 illustrates an example backplate that includes a groove for a bus bar for backside power delivery.

FIG. 4 illustrates an example bus bar to be inserted into the groove of the example backplate of FIG. 3.

FIG. 5 illustrates an example backplate assembly corresponding to the example backplate of FIG. 3 in combination with the example bus bar of FIG. 4.

FIG. 6 illustrates the results of a finite element analysis showing warpage in the known backplate of FIGS. 1 and 2.

FIG. 7 illustrates the results of a finite element analysis showing warpage in the example backplate of FIGS. 3-5.

FIG. 8 illustrates the results of a finite element analysis showing warpage in another example backplate that is thicker than the one represented in FIG. 7.

FIG. 9 illustrates an example composite backplate with composite layers constructed in accordance with teachings disclosed herein.

FIG. 10 is a simplified cross-sectional view of the example composite backplate of FIG. 9.

FIG. 11 is a cross-sectional view of another example composite backplate constructed in accordance with teachings disclosed herein.

FIG. 12 is a cross-sectional view of another example composite backplate constructed in accordance with teachings disclosed herein.

FIG. 13 is a cross-sectional view of another example composite backplate constructed in accordance with teachings disclosed herein.

FIG. 14 is a top view of another example composite backplate constructed in accordance with teachings disclosed herein.

FIG. 15 is a cross-sectional view of the example composite backplate of FIG. 14 taken along the line 15-15 shown in FIG. 14.

FIG. 16 is a cross-sectional view of the example composite backplate of FIG. 14 taken along the line 16-16 shown in FIG. 14.

FIG. 17 is a flowchart representative of an example method of manufacturing any of the example composite backplates of FIGS. 9-16.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

Integrated circuit (IC) packages, such as central processing units (CPUs) or other processor chips, are often coupled to printed circuit boards (PCBs) via sockets. Many sockets, including land grid array (LGA) sockets, include a plurality of pins that receive and electrically couple to corresponding features (e.g., contacts or lands) of the IC package. To ensure that the IC package is able to communicate with the circuit board, the pins of the socket must remain in contact with the IC package. In many examples, the contact force between the pins of the socket and the IC package is provided by one or more fasteners coupled between a heatsink, disposed on the IC package (e.g., opposite the socket), and a backplate disposed on an opposite side of the printed circuit board relative to the socket and the IC package. Such assemblies of components are referred to herein as IC package heat dissipating component stacks. The fasteners that secure such component stacks together with sufficient compressive force to ensure electrical contact between the socket and IC package can cause warpage or bending of the backplate, the printed circuit board, and/or other components in the component stack. Such bending or warpage can reduce the contact force in particular areas of the socket. One solution to this problem is to increase the thickness of the backplate, thereby increasing the stiffness of the backplate. However, in many situations such a solution is not a viable option because of space constraints.

Another challenge with reducing warpage in backplates arises when the backplates are to include or carry one or more bus bars to provide backside power delivery to an IC package inserted into a socket on a printed circuit board opposite to the backplate. Such a bus bar can interfere with the ability of a backplate to interface with and, thus, provide structural support to the printed circuit board and the associated socket. One solution is to embed the bus bar into the backplate and/or position the bus bar within a groove etched or machined into a surface of the backplate. While the groove in the backplate provides room for the bus bar, the groove reduces the strength or stiffness of the backplate, which can lead to increase warpage and, thus, less reliable contact between an IC package and an associated socket.

Examples disclosed herein include backplates with grooves for bus bars, where the backplates include high stiffness materials to provide strength that compensates for the presence of the grooves. In some examples, the high strength material is used in combination with known materials (e.g., steel). Such backplates (e.g., composite backplates) disclosed herein are able to facilitate backside power deliver (e.g., with a groove for a bus bar) without increasing the overall thickness of the backplates relative to known non-backside power delivery backplates (e.g., backplates that do not include a groove for a bus bar). Thus, examples disclosed herein do not require additional space in constrained areas that would otherwise be needed using known techniques.

FIG. 1 illustrates an exploded view of a known integrated circuit (IC) package heat dissipating component stack 100. In FIG. 1, the component stack 100 includes a heatsink 102, a carrier 104 (e.g., a package carrier, a carrier plate), an integrated circuit (IC) package 106, a bolster plate 108, a socket 110 coupled to a printed circuit board (PCB) 112 (e.g., a motherboard), and a backplate 114.

The IC package 106 includes one or more electrical circuits on a semiconductor substrate. The IC package 106 can perform processing functions, memory functions, and/or any other suitable functions. The IC package 106 can include any type of processing circuitry, including programmable microprocessors, one or more FPGAs, one or more CPUs, one or more GPUs, one or more DSPs, one or more XPUs, one or more ASICs, and/or one or more microcontrollers. In FIG. 1, the IC package 106 is a land grid array (LGA) processor chip. Additionally or alternatively, the IC package 106 can be one of a ball grid array (BGA) processor chip or a pin grid array (PGA) processor chip instead. Further, other types of IC packages can be used in the component stack 100 instead of a processor chip (e.g., a memory chip). In FIG. 1, the carrier 104 is used to couple the heatsink 102 to the IC package 106 prior to assembly of the entire component stack 100. Sometimes the combination of the heatsink 102, the carrier 104, and the IC package 106 is referred to as a processor heatsink loading mechanism (PHLM).

In FIG. 1, the heatsink 102 is couplable (e.g., thermally couplable) to the IC package 106 to dissipate heat therefrom. In FIG. 1, the heatsink 102 is mechanically coupled to the backplate 114 via fixture elements, loading mechanisms, or fasteners 116 to place the components between the heatsink 102 and the backplate 114 within the component stack 100 in compression when assembled. In some instances, the heatsink 102 is coupled to the backplate 114 via the bolster plate 108 positioned therebetween. More particularly, as shown in FIG. 1, the bolster plate 108 is couplable to a top surface 118 of the PCB 112 while the backplate 114 is couplable to a bottom surface 120 of the PCB 112 opposite the bolster plate 108. In this manner, the PCB 112 is sandwiched between the bolster plate 108 and the backplate 114. The bolster plate 108 is constructed to surround the socket 110 positioned on the top surface 118 of the PCB 112.

The socket 110 communicatively couples the IC package 106 to the printed circuit board 112. In FIG. 1, the socket 110 is a land grid array (LGA) socket, which includes a plurality of pins within the socket arranged to interface (e.g., electrically couple) with corresponding contacts or lands on the IC package 106. In other instances, the socket 110 can be implemented by any other suitable type of socket (e.g., a ball grid array, a pin grid array, etc.) suitable to receive and interface with the IC package 106. The compression created by the mechanical coupling of the heatsink 102 to the backplate 114 via the fasteners 116 serves to ensure that corresponding connectors (e.g., pins, lands, etc.) on the socket 110 and the IC package 106 remain in contact.

In some known heat dissipating component stacks, the fasteners 116 are located near the four corners of the heatsink. By contrast, in FIG. 1, the fasteners 116 are located along the long edges of the heatsink 102. Regardless of the particular location of the fasteners 116, the fasteners 116 are along the outer perimeter of the components in the component stack 100. Due to the location of the fasteners 116, the tightening of the fasteners 116 causes a compressive force to be applied to the edges or outer perimeter of the component stack 100 (e.g., along the sides of the heatsink 102 and the backplate 114). The locations at which the compressive force acts on the component stack 100 results in the components bending, bowing, warping, and/or deflecting. More particularly, in some instance, the IC package 106 and the socket 110 bend or bow in opposite directions (e.g., the central regions of the interfacing components are deflected apart from one another). Such warpage in the components can result in a gap or separation between the IC package 106 and the socket 110. The gap or separation is typically the greatest near a center of the IC package 106 and the socket 110 and can lead to insufficient contact between the connectors in the IC package 106 and the socket 110, thereby leading to degradation in performance of the IC package 106 (if not rendering the IC package 106 inoperable).

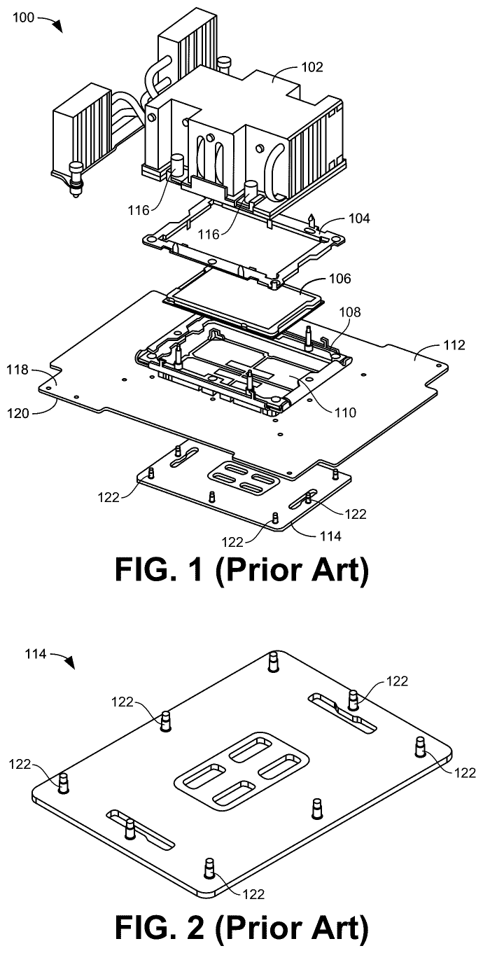

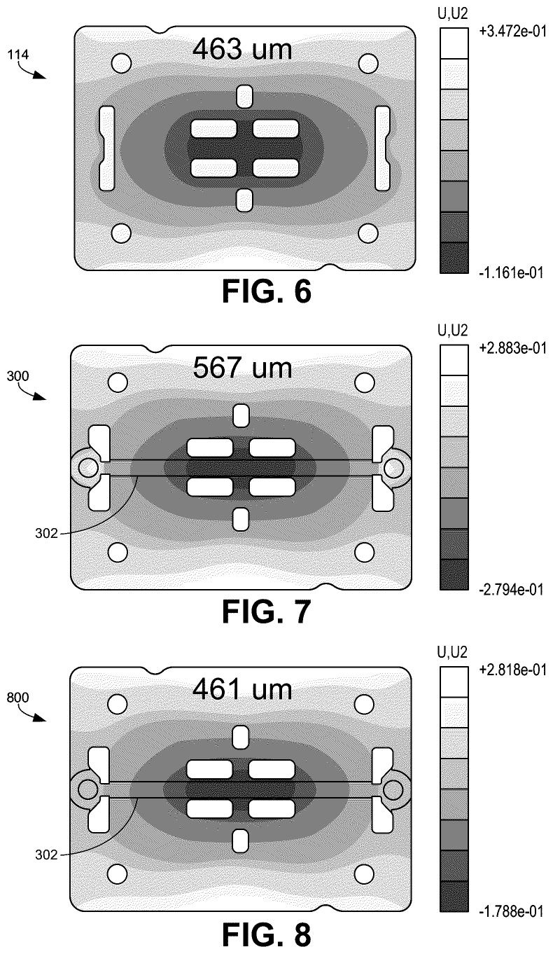

Warpage of components in the component stack 100 of FIG. 1 can be reduced by increasing the strength and/or stiffness of the components including the backplate 114. FIG. 2 illustrates an enlarged view of the known backplate 114 of FIG. 1. The known backplate 114 of FIGS. 1 and 2 is defined by a flat steel plate with eight studs 122 that connect with the bolster plate 108 on the opposite side (e.g., front side, top side) of the printed circuit board 112. In some implementations, the backplate 114 has a thickness of 2.5 millimeters (mm), which provides adequate strength or stiffness. More particularly, the finite element analysis represented in FIG. 6 shows that such a backplate 114 results in approximately 463 micrometers (μm) of deformation or warpage across the surface of the backplate 114.

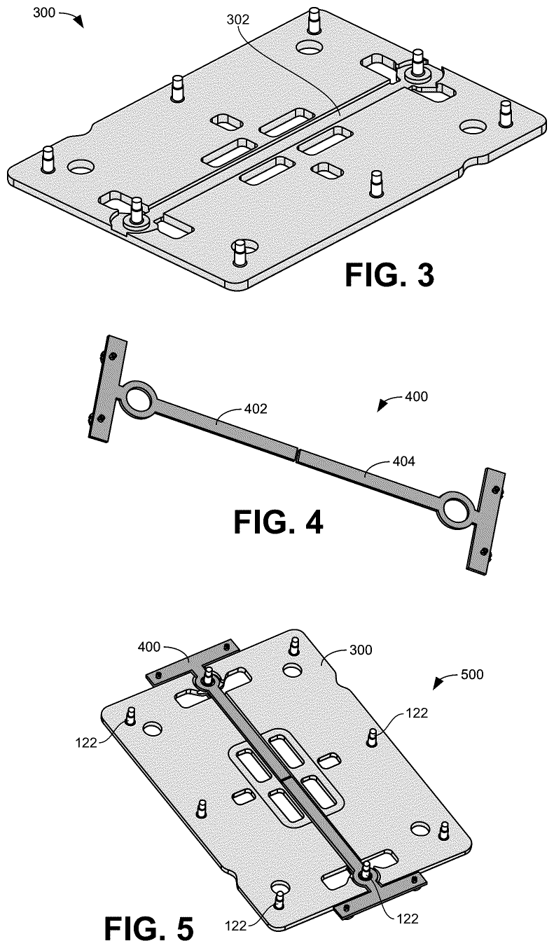

A total deflection of 463 μm or less in the backplate 114 is within acceptable limits to ensure adequate contact between the socket 110 and the IC package 106. However, in some implementations of backside power delivery, a bus bar can be positioned to extend along the face of the backplate 114 to provide an electrical path to the back side of the socket 110. In some examples, to reduce (e.g., avoid) interference between the upper surface of the backplate 114 and the printed circuit board 112 and/or interference with the studs 122, the bus bar may be inset within a groove cut or otherwise machined into the backplate 114. For instance, FIG. 3 illustrates an example backplate 300 similar to the backplate 114 of FIG. 2, except that the example backplate 300 of FIG. 3 includes a groove 302. FIG. 4 illustrates an example bus bar 400 to be inserted into the groove 302 of the example backplate 300 of FIG. 3. FIG. 5 illustrates an example backplate assembly 500 corresponding to the backplate 300 of FIG. 3 with the bus bar 400 of FIG. 4 within the corresponding groove 302. In this example, the bus bar 400 is in two parts (e.g., a first portion 402 and a second portion 404) to provide dual entry power delivery.

In the illustrated example of FIGS. 3-5, the groove 302 is 1.2 mm deep (in a 2.5 mm thick backplate 300). Thus, in this example, the groove 302 is less than half the overall thickness of the backplate 300. In other examples, the groove 302 is half the overall thickness of the backplate 300. In other examples, the groove 302 is more than half the overall thickness of the backplate 300. While the groove 302 provides room for the bus bar 400 without interfering with the outer surface of the backplate 300 or the studs 122, the groove 302 reduces the rigidity or stiffness of the backplate 300. More particularly, the finite element analysis represented in FIG. 7 shows that, as compared with the backplate 114 of FIGS. 1 and 2, the warpage in the backplate 300 increases more than 20% up to 567 μm of deflection (as compared with the 463 μm of deflection shown in FIG. 6 for the backplate 114 of FIGS. 1 and 2.). This is a significant increase in warpage that can cause significant structural risks related to socket-package contact, creep, shock, and vibration, etc.

A potential approach to mitigate against the increased warpage caused by the groove 302 is to increase the overall thickness of the backplate 300. For example, the finite element analysis represented in FIG. 8 is for another example backplate 800 that is similar to the example backplate 300 shown in FIG. 7, except that the backplate 800 of FIG. 8 is 0.3 mm thicker (e.g., 2.8 mm thick instead of 2.5 mm thick). As shown, the added thickness reduces the warpage down to approximately 461 μm, which is comparable to the warpage of the backplate 114 (that does not include a groove) as shown in FIG. 6. While the increased thickness of the example backplate 800 represented in FIG. 8 mitigates against warpage arising from the groove 302, such solutions may not be suitable when the backplate 800 is to be implemented in a system with tight space constraints. For instance, the increase in backplate thickness may result in interference between the backside power delivery backplate and a known chassis used for existing backplates (that are thinner but do not provide backside power deliver). For instance, the thicker backplate may interfere with embossing features on the chassis base pan.

Examples disclosed herein include a backplate that is a composite of two or more materials. In some examples, the materials include a first material such as steel and a second material that is stiffer than the first material. In some examples, the first material is steel. Steel by itself (e.g., alone) is used in known backplates. The higher stiffness material (e.g., the second material) increases the overall stiffness of the composite backplate, thereby reducing warpage without the need for increased thickness. Thus, teachings disclosed herein increase backplate stiffness and enable the backplate thickness to stay consistent with existing backplate thicknesses while at the same time including a groove for a bus bar to provide for backside power delivery.

Teachings disclosed herein also provide an alternative multi-entry power delivery backplate manufacturing process with a layered backplate. Specifically, rather than machining a groove into a unitary piece of metal, a groove is defined by an upper surface of the second (e.g., high stiffness) material and the edges of two portions of the first material (e.g., steel) positioned on the upper surface of the high stiffness material.

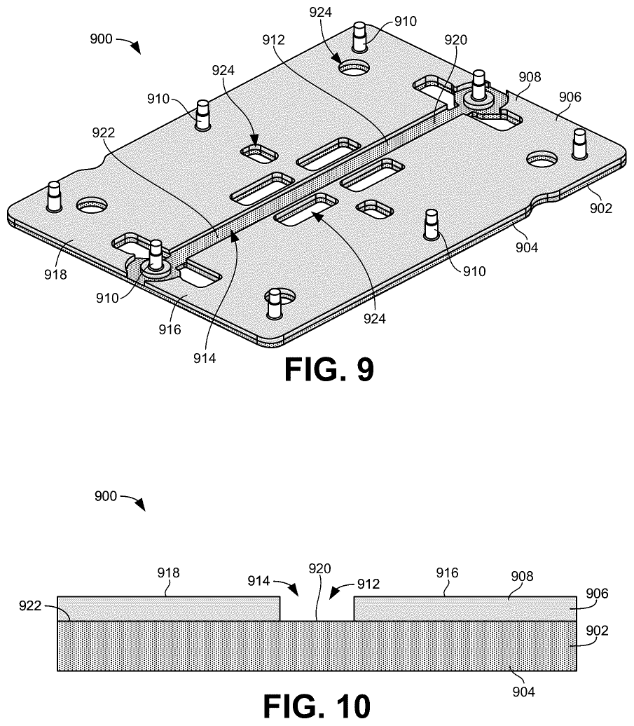

FIG. 9 illustrates an example backplate 900 (e.g., composite backplate) with composite layers constructed in accordance with teachings disclosed herein. FIG. 10 illustrates a simplified cross-sectional view of the example backplate 900 of FIG. 9. As shown in the illustrated example, the backplate 900 includes: (1) a high stiffness layer 902 (e.g., bottom layer, high stiffness plate) that includes a high stiffness material 904, and (2) a stud support layer 906 (e.g., top layer, metal layer, metal plate) that includes metal 908 (e.g., steel) or other suitable material for embedding and/or supporting the studs 910. In some examples, the studs 910 are made of the same material as the stud support layer 906 (e.g., steel). In other examples, the studs 910 are made of a different material. In some examples, the studs 910 are integrally formed with the stud support layer 906. In other examples, the studs 910 are attached to the stud support layer 906 in any suitable manner (e.g., welding, an adhesive, threaded engagement, etc.).

The high stiffness material 904 enables the backplate 900 to be thinner than possible using known backplates. More particularly, in some examples, the backplate 900 has the same thickness as known backplates implemented without the groove for bus bars (e.g., the non-backside power delivery backplate 114 of FIGS. 1 and 2). In some examples, the groove 912 for a bus bar is achieved without machining. Instead, as shown in FIG. 9 and more clearly in FIG. 10, the groove 912 is defined merely as a gap 914 (e.g., space) adjacent (e.g., between) different portions or regions (e.g., a first portion 916 and a second portion 918) of the stud support layer 906, with the bottom 920 (e.g., base) of the groove 912 defined by the outer surface 922 (e.g., the top surface) of the high stiffness layer 902 onto which the stud support layer 906 is attached. That is, in some examples, the outer surface 922 is a planar surface on to which both portions 916, 918 of the stud support layer 906 as well as the bus bar 400 are to be attached. However, in this example, the portions 916, 918 of the stud support layer 906 and the bus bar 400 are attached to different areas of the planar surface. In other words, the bus bar 400 is laterally offset relative to the portions 916, 918 of the stud support layer 906 along the outer surface 922 of the high stiffness layer 902.

In some examples, the groove 912 extends the full length of the backplate 900. As a result, the different portions 916, 918 of the stud support layer 906 are distinct and separate from one another. In other examples, the different portions 916, 918 can be connected and/or integrally formed. For instance, in some examples, a narrow portion of the stud support layer 906 can extend between the two portions 916, 918 near the middle of the groove 912 between the inner ends of the two portions of the bus bar (e.g., the portions 402, 404 of the bus bar 400 shown in FIG. 4). This narrow portion of material connecting the two portions 916, 918 effectively divides the groove 912 shown in FIG. 9 into two separate grooves. In some examples, multiple (e.g., more than two) grooves may be provided to enable multiple (e.g., more than two) different bus bars spaced apart from one another. Additionally or alternatively, in some examples, the number, shape, and/or size of the different portions 916, 918 of the stud support layer 906 can be suitably adapted to provide for any suitable number of bus bars having any suitable size (e.g., width and length) and any suitable shape (e.g., straight, curved, etc.).

In some examples, in addition to the groove 912 (defined by the gap 914 between different portions 916, 918 of the stud support layer 906), the stud support layer 906 can include other openings, gaps, and/or cavities to provide room for capacitors and/or other electronic components on the bottom side of an associated printed circuit board (e.g., the PCB 112 of FIG. 1). In some examples, such cavities also extend into and/or through the high stiffness layer 902, as shown by the openings 924 in FIG. 9. Additionally or alternatively, in some examples, the cavities extend through the stud support layer 906 but not the high stiffness layer 902.

In some examples, as illustrated in FIG. 10, the high stiffness layer 902 is thicker than the stud support layer 906. In other examples, the stud support layer 906 is thicker than the high stiffness layer 902. In other examples, the stud support layer 906 has a same thickness as the high stiffness layer. In some examples, the thickness of the stud support layer 906 is determined by the thickness of the bus bar (e.g., the bus bar 400 of FIG. 4) to be inserted into the groove 912. More particularly, in some examples, the stud support layer 906 is at least as thick as the bus bar 400. In some examples, the stud support layer 906 is slightly thicker than the bus bar 400 to allow for some clearance and/or to permit the insertion of insulating layer(s) and/or liner(s) to electrically isolate the bus bar 400 from conductive portions of the backplate 900 and/or conductive elements on the backside of the PCB 112.

In some examples, the high stiffness material 904 includes tungsten, tungsten carbide, tungsten nitride, and/or other high stiffness metal. In other examples, the high stiffness material 904 includes a ceramic (e.g., aluminum oxide) instead of and/or in addition to metal. In some examples, the different layers of material of the backplate 900 are combined through any suitable manufacturing processes, such as adhesive bonding, metal injection molding (MIM), brazing, ultrasonic welding, etc.

Finite element analysis has been performed on a model composite backplate constructed according to the example backplate 900 of FIGS. 9 and 10. The results of this analysis, when compared with previous backplate designs, reveals that an example composite backplate (with a bus bar groove) that is 2.5 mm thick can achieve approximately the same warpage as a non-composite backplate with a thickness of 2.8 mm, thereby saving on 0.3 mm of thickness. In other words, example composite backplates with a bus bar groove disclosed herein achieve approximately the same warpage as non-composite backplates without a bus bar groove at the same thickness of 2.5 mm. Keeping the same backplate thickness eliminates system level keep out zone (KOZ) issues for future platforms based on existing chassis designs (e.g., space constraints of existing chassis).

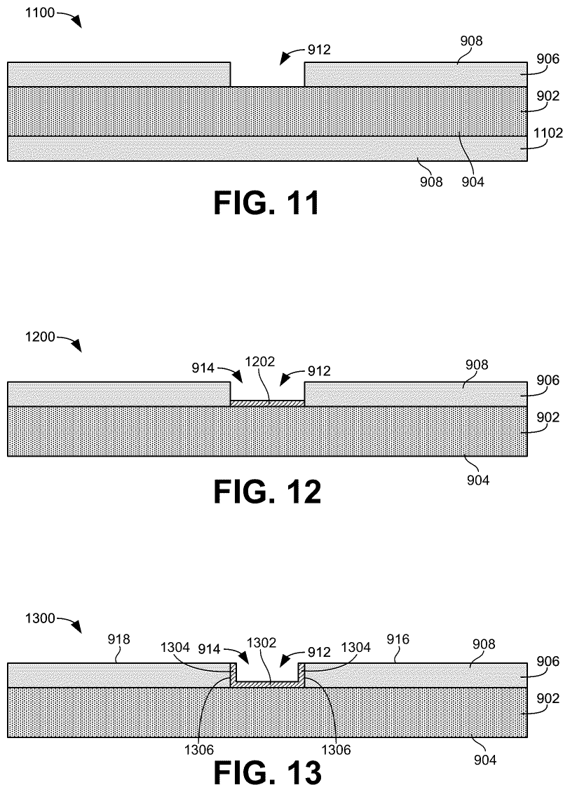

Although the backplate 900 of FIGS. 9 and 10 is shown as having two different layers of material, in other examples, there may be more than two layers of material. For instance, FIG. 11 illustrates another example composite backplate 1100 where an additional metal layer 1102 is added to the bottom of the assembly (e.g., the bottom side of the high stiffness layer 902). That is, in the illustrated example of FIG. 11, the high stiffness layer 902 is sandwiched between the stud support layer 906 and a separate metal layer 1102 on opposite sides of the high stiffness layer 902. In some examples, the additional metal layer 1102 layer serves to facilitate the embedding and/or supporting of the studs 910 (shown in FIG. 9) and/or to protect the high stiffness material 904. In the illustrated example of FIG. 11, the additional metal layer 1102 is made of the same material (e.g., steel) as the top stud support layer 906. In other examples, the additional metal layer 1102 is a different metal from the top stud support layer 906. In some examples, the additional layer 1102 can be implemented by a material other than metal.

In some examples, the thickness of each of the layers 902, 906, 1102 can be adjusted to maintain a consistent overall thickness relative to the example backplate 900 of FIGS. 9 and 10. That is, in some examples, the two metal layers 906, 1102 can be thinner than in the example backplate 900 of FIGS. 9 and 10. However, in some examples, the thickness of the upper stud support layer 906 is determined by the thickness of the bus bar (e.g., to define a suitable depth for the groove 912 to fully contain the bus bar). Accordingly, in some examples, the high stiffness layer 902 in FIG. 11 can be thinner than the corresponding high stiffness layer 902 in FIG. 10 to achieve the same overall thickness. In some examples, when there are fewer space constraints, the additional layers of material can add to the overall thickness. In some examples, there can be multiple (e.g., at least two) high stiffness layers 902 and multiple metal layers 906, 1102 with the different layers alternating in a stack.

FIG. 12 illustrates another example composite backplate 1200 that includes an example spacer 1202 corresponding to a flat piece of material positioned between and extending across (e.g., spanning) the gap 914 defining the groove 912. In some examples, the spacer 1202 is included to cover (e.g., protect) the high stiffness material 904 that would otherwise be exposed within the groove 912. Thus, the spacer 1202 serves to separate (e.g., is positioned between) the bus bar 400 and the high stiffness layer 902. FIG. 13 illustrates another example composite backplate 1300 that includes another example spacer 1302 corresponding to a U-shaped piece of material positioned between and extending across (e.g., spanning) the gap 914 defining the groove 912. As compared with the example of FIG. 12, the spacer 1302 in FIG. 13 includes sidewalls 1304 that protrude away from the high stiffness layer 902 to cover (e.g., protect) the side edges 1306 of the different portions 916, 918 of the stud support layer 906. Thus, the spacer 1302 serves to separate the bus bar 400 from the different portions 916, 918 of the stud support layer 906. In some examples, the spacers 1202, 1302 of FIGS. 12 and/or 13 are made of plastic or some other electrically insulative (e.g., dielectric) material. In other examples, the spacers 1202, 1302 are made of metal or other stiff material to provide additional structural support to the backplate assembly. In some examples, the additional metal layer 1102 discussed above in connection with FIG. 11 can be included in the illustrated examples of FIG. 12 and/or 13.

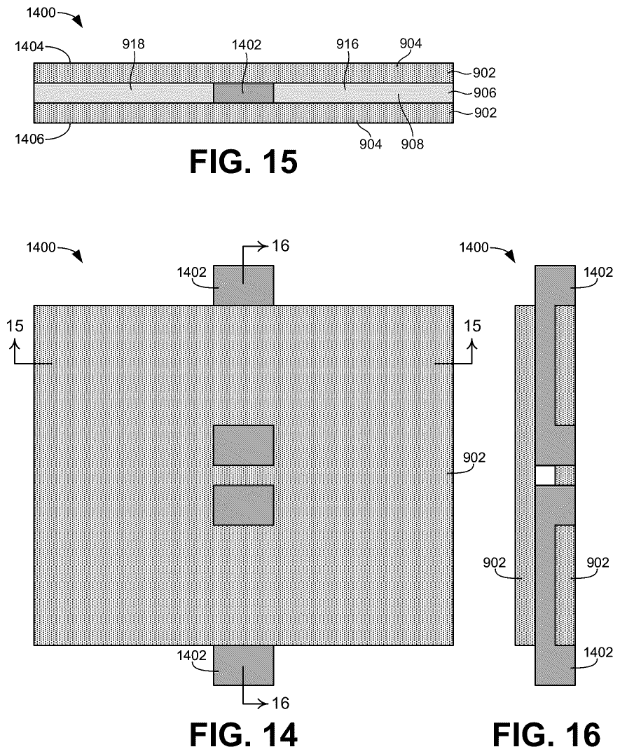

FIG. 14-16 illustrate another example composite backplate 1400 that includes dual bus bars 1402 that are embedded between outer surfaces 1404, 1406 of the backplate 1400. That is, in this example, the bus bars 1402 are enclosed above and below by two separate high stiffness layers 902 of the high stiffness material 904. In this example, the two high stiffness layers 902 are made of the same material (e.g., the same metal 908, which may include steel). In other examples, the different high stiffness layers 902 can be made of different high stiffness materials.

As shown in the illustrated example, the bus bar 1402 is positioned adjacent (e.g., between) two different portions 916, 918 of the stud support layer 906 that is also sandwiched between the two high stiffness layers 902. In some examples, the additional metal layers and/or additional high stiffness layers, as discussed above in connection with FIG. 11, can be included in the illustrated example of FIGS. 14-16. Additionally or alternatively, in some examples, the spacers 1202, 1302, discussed above in connection with FIGS. 13 and 14, can be included in the illustrated example of FIGS. 14-16.

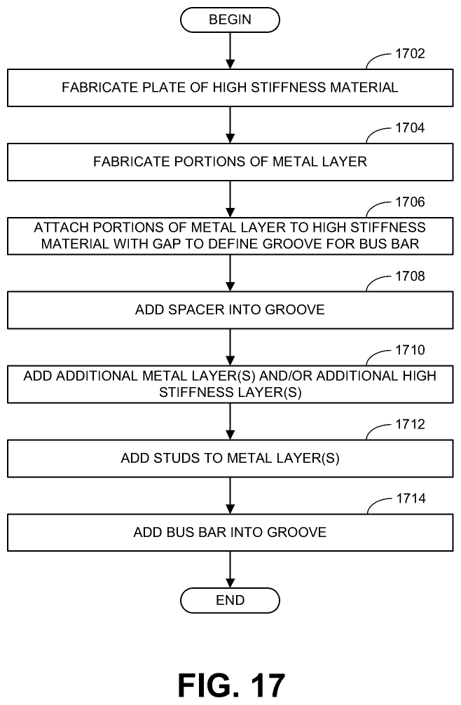

FIG. 17 is a flowchart representative of an example method of manufacturing any of the example backplates of FIGS. 9-16. Although the example method of manufacture is described with reference to the flowchart illustrated in FIG. 17, many other methods may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example.

The example process begins at block 1702 by fabricating a plate of high stiffness material (e.g., the high stiffness layer 902 of the high stiffness material 904). In some examples, the fabrication of the plate of high stiffness material includes providing openings or cavities (e.g., the openings 924) within the plate that provide room for capacitors and/or other components on a backside of a printed circuit board. At block 1704, the example process includes fabricating portions of a metal layer (e.g., the stud support layer 906). In some examples, this includes fabricating multiple distinct portions of metal (e.g., the portions 916, 918) that are to be separately attached to the high stiffness layer 902. In other examples, the different portions can be connected and part of a single unitary piece of metal with gaps or openings to define the location of the groove 912. In some examples, the fabrication of the portions of the stud support layer 906 includes providing additional openings or cavities (e.g., the openings 924) within the stud support layer 906 that provide room for capacitors and/or other components on a backside of a printed circuit board.

At block 1706, the example process includes attaching the portions of the stud support layer 906 to the plate of high stiffness material with a gap (e.g., the gap 914) to define a groove (e.g., the groove 912) for a bus bar (e.g., the bus bars 400, 1402). In some examples, the order in which blocks 1702-1706 are implemented can differ from what is shown and/or aspects discussed above can be consolidated and/or implemented in different ways. For instance, in some examples, the metal layer is fabricated first (block 1704), followed by the fabrication of the plate of high stiffness material (block 1702). Further, in some such examples, the two layers are attached (block 1706) at the same time that the plate of high stiffness material is fabricated. Specifically, in some examples, when the high stiffness material is a ceramic, the fabricated metal layer can be deposited within ceramic powder that is then sintered to produce the plate of high stiffness material. This process also achieves the bond or connection between the metal layer and the high stiffness material. In other examples, when the high stiffness material includes tungsten, the metal layer (which has a much lower melting temperature) may be fabricated through a metal injection molding process directly onto the high stiffness material. Thus, in such examples, the metal layer is fabricated in the same process as when it is being attached to the plate of high stiffness material. In other examples, blocks 1702 and 1704 can be done in parallel as the two layers of material are separately fabricated and then subsequently combined at block 1706. In some such examples, the layers are combined using adhesive bonding, brazing, ultrasonic welding, and/or any suitable manufacturing processes. In some examples, the openings 924 are added (e.g., via drilling) to the joined layers of material after being combined rather than adding the openings 924 before the layers are combined.

At block 1708, the example process includes adding a spacer into the groove. In some examples, the spacer is a flat piece of material such as the example spacer 1202 shown in FIG. 12. In some examples, the spacer is a U-shaped piece of material such as the example spacer 1302 shown in FIG. 13. In some examples, block 1708 is omitted.

At block 1710, the example process includes adding additional metal layer(s) and/or additional high stiffness layer(s). In some examples, the additional layer can be added to the underside of the assembly (as shown in FIG. 11) or on the top side of the assembly (e.g., as shown in FIG. 14). In some examples, additional layers can be added to both sides of the initial combination of the metal and high stiffness layers. In some examples, block 1710 is omitted.

At block 1712, the example process includes adding studs (e.g., the studs 910) to the metal layer(s). The studs can be connected to the metal layer(s) via adhesive bonding, welding, threaded engagement, etc. In some examples, the studs 910 can be added to the metal layer(s) earlier in the process than what is represented in FIG. 17. In some examples, the studs 910 are integral protrusions of the metal layer and, thus, added when the metal layer is initially fabricated (at block 1704).

At block 1714, the example process includes adding a bus bar into the groove. In some examples, such as when the bus bar is to be embedded between outer layers of backplate (as in the illustrated example shown in FIGS. 14-16), the bus bar is added earlier in the process (e.g., before adding the additional layer(s) at block 1710). Thereafter, the example process of FIG. 17 ends.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed including, for instance, backplates having bus bars for backside power delivery that do not sacrifice the rigidity of the backplate while maintaining warpage within acceptable limits. Such backplates are implemented by combining at least one metal layer to at least one high stiffness layer. Further, some example composite backplates disclosed herein provide the additional benefit that there is no need to machine the backplate to include a groove for the bus bar. Instead, such a groove is provided by shaping different portions of the metal layer and positioning them with a gap therebetween. The gap defines the width of the resulting groove, with the base or bottom of the groove defined by the surface of the underlying high stiffness material onto which the different portions of the metal layer are attached.

Further examples and combinations thereof include the following:

Example 1 includes a backplate comprising a first layer including a first material, a second layer attached to the first layer, the second layer including a second material different from the first material, and a bus bar attached to the first layer.

Example 2 includes the backplate of example 1, wherein the first material is stiffer than the second material.

Example 3 includes the backplate of any one of examples 1 or 2, further including a third layer attached to the first layer, the second layer attached to a first side of the first layer, the third layer attached to a second side of the first layer, the second side opposite the first side, the third layer including a third material different from the first material.

Example 4 includes the backplate of any one of examples 1 or 2, further including a third layer attached to the second layer, the second layer between the first layer and the third layer, the third layer including a third material different from the second material.

Example 5 includes the backplate of example 4, wherein the bus bar is embedded between the first layer and the third layer.

Example 6 includes the backplate of any one of examples 1-5, wherein the first layer has a first thickness, and the second layer has a second thickness, the second thickness different from the first thickness.

Example 7 includes the backplate of any one of examples 1-7, further including a spacer between the bus bar and the first layer.

Example 8 includes the backplate of example 7, wherein the spacer includes an electrically insulative plastic.

Example 9 includes the backplate of example 7, wherein the spacer includes a metal.

Example 10 includes the backplate of any one of examples 7-9, wherein the bus bar is between different portions of the second layer, and the spacer is flat and extends between the different portions of the second layer.

Example 11 includes the backplate of any one of examples 7-9, wherein the spacer has a U-shaped cross-section with sidewalls that protrude from the first layer, the sidewalls to separate the bus bar from different portions of the second layer on either side of the bus bar.

Example 12 includes the backplate of any one of examples 1-11, wherein the first layer includes a planar surface, and the bus bar and the second layer are attached to different areas of the planar surface.

Example 13 includes an apparatus comprising a first plate including a first material, a bus bar extending along a first surface of the first plate, a first portion of a second plate bonded to the first surface of the first plate, the second plate including a second material, the first material stiffer than the second material, and a second portion of the second plate bonded to the first surface of the first plate, the first and second portions of the second plate extending along opposite sides of the bus bar.

Example 14 includes the apparatus of any one of examples 1-13, wherein the second material is steel.

Example 15 includes the apparatus of example 14, wherein the first material includes tungsten.

Example 16 includes the apparatus of example 15, wherein the first material includes at least one of carbon or nitrogen.

Example 17 includes the apparatus of any one of examples 1-14, wherein the first material includes a ceramic.

Example 18 includes the apparatus of example 17, wherein the first material includes aluminum and oxygen.

Example 19 includes an apparatus comprising a circuit board, a socket on a first side of the circuit board, and a backplate mountable to a second side of the circuit board opposite the first side, the backplate including a first layer, a second layer, the second layer between the first layer and the circuit board, and a bus bar between the first layer and the circuit board, the bus bar offset relative to the second layer along a surface of the first layer.

Example 20 includes the apparatus of example 19, wherein the first layer has a first thickness, the second layer has a second thickness, and the bus bar has a third thickness, the first thickness less than the second thickness, the first thickness greater than or equal to the third thickness.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A backplate comprising:
a first layer including a first material;
a second layer attached to the first layer, the second layer including a second material different from the first material; and
a bus bar attached to the first layer.

2. The backplate of claim 1, wherein the first material is stiffer than the second material.

3. The backplate of claim 1, further including a third layer attached to the first layer, the second layer attached to a first side of the first layer, the third layer attached to a second side of the first layer, the second side opposite the first side, the third layer including a third material different from the first material.

4. The backplate of claim 1, further including a third layer attached to the second layer, the second layer between the first layer and the third layer, the third layer including a third material different from the second material.

5. The backplate of claim 4, wherein the bus bar is embedded between the first layer and the third layer.

6. The backplate of claim 1, wherein the first layer has a first thickness, and the second layer has a second thickness, the second thickness different from the first thickness.

7. The backplate of claim 1, further including a spacer between the bus bar and the first layer.

8. The backplate of claim 7, wherein the spacer includes an electrically insulative plastic.

9. The backplate of claim 7, wherein the spacer includes a metal.

10. The backplate of claim 7, wherein the bus bar is between different portions of the second layer, and the spacer is flat and extends between the different portions of the second layer.

11. The backplate of claim 7, wherein the spacer has a U-shaped cross-section with sidewalls that protrude from the first layer, the sidewalls to separate the bus bar from different portions of the second layer on either side of the bus bar.

12. The backplate of claim 1, wherein the first layer includes a planar surface, and the bus bar and the second layer are attached to different areas of the planar surface.

13. An apparatus comprising:
a first plate including a first material;
a bus bar extending along a first surface of the first plate;
a first portion of a second plate bonded to the first surface of the first plate, the second plate including a second material, the first material stiffer than the second material; and
a second portion of the second plate bonded to the first surface of the first plate, the first and second portions of the second plate extending along opposite sides of the bus bar.

14. The apparatus of claim 13, wherein the second material is steel.

15. The apparatus of claim 14, wherein the first material includes tungsten.

16. The apparatus of claim 15, wherein the first material includes at least one of carbon or nitrogen.

17. The apparatus of claim 14, wherein the first material includes a ceramic.

18. The apparatus of claim 17, wherein the first material includes aluminum and oxygen.

19. An apparatus comprising:
a circuit board;
a socket on a first side of the circuit board; and
a backplate mountable to a second side of the circuit board opposite the first side, the backplate including:
a first layer,
a second layer, the second layer between the first layer and the circuit board, and
a bus bar between the first layer and the circuit board, the bus bar offset relative to the second layer along a surface of the first layer.

20. The apparatus of claim 19, wherein the first layer has a first thickness, the second layer has a second thickness, and the bus bar has a third thickness, the first thickness less than the second thickness, the first thickness greater than or equal to the third thickness.
